(19) United States
(12) Patent Application Publication
(10) Pub. No.: US 2026/0110761 A1
(43) Pub. Date: Apr. 23, 2026

(54) Apparatus and Method for Coupling Thermal Imaging Equipment with an MRI Apparatus

(71) Applicant: Michael Oumano, Warwick, RI (US)

(72) Inventor: Michael Oumano, Warwick, RI (US)

(21) Appl. No.: 19/352,328

(22) Filed: Oct. 7, 2025

Related U.S. Application Data
(60) Provisional application No. 63/708,450, filed on Oct. 17, 2024.

(51) Int. Cl. G01R 33/28; G06N 3/08

(52) U.S. Cl. CPC G01R 33/288; G06N 3/08

(57) ABSTRACT

An apparatus and method for monitoring thermal events during Magnetic Resonance Imaging (MRI) scans uses artificial intelligence to enhance patient safety. The system aims to detect and alert to potentially dangerous heating, which can occur during MRI procedures. The apparatus has a thermal-imaging camera that communicates with an MRI system to monitor temperatures on and around a patient during an MRI procedure. In the event of unsafe temperatures, the apparatus and method may sound an alarm and/or give a visual signal, proceed to abort the scan, or alert the technologist to do so.

### TECHNICAL FIELD

The present disclosure relates generally to thermal-image data processing and more specifically to devices, systems and methods for magnetic resonance imaging and safety thereof.

### BACKGROUND OF THE INVENTION

Magnetic Resonance Imaging (MRI) is a widely used medical imaging technique that provides detailed images of internal body structures. It is based on the principles of nuclear magnetic resonance (NMR), where atomic nuclei in a strong magnetic field are exposed to radiofrequency (RF) pulses. This interaction induces the nuclei to emit signals that are detected and processed to generate high-resolution images of tissues and organs.

Despite its non-invasive nature and superior soft-tissue contrast, MRI requires safety precautions. The rapid switching of magnetic fields, especially RF fields and gradient pulses, can induce electrical currents in conductive materials or tissues. This can lead to heating effects and, in some cases, severe burns. These burns can occur due to mechanisms such as contact burns, loop burns from conductive materials forming a circuit, and burns around implanted medical devices or wires. Additionally, the presence of malfunctioning equipment, such as frayed insulation or exposed wiring, can further elevate the risk of patient injury.

Patients must be monitored during MRI operation. MRI technologists rely primarily on video surveillance and intercom systems to observe patients during scans. These tools are often insufficient, particularly for unconscious or sedated patients who cannot report discomfort or pain. As a result, there is a need for improved methods and systems for monitoring and preventing patient injuries during MRI procedures, especially those related to thermal effects and burns.

### SUMMARY OF THE INVENTION

An apparatus and method for monitoring thermal events during Magnetic Resonance Imaging (MRI) scans uses artificial intelligence to enhance patient safety. The system aims to detect and alert to potentially dangerous heating, which can occur during MRI procedures. The apparatus has a thermal-imaging camera that communicates with an MRI system to monitor temperatures on and around a patient during an MRI procedure. In the event of unsafe temperatures, the apparatus and method may sound an alarm and/or give a visual signal, proceed to abort the scan, or alert the technologist to do so.

The apparatus includes an MRI scanner, at least one thermal-imaging camera to detect infrared radiation, and a data-acquisition unit. This unit, a computer, runs a software program with a thermal-anomaly detection algorithm to analyze thermal images in real time and identify anomalous heating. The system also incorporates a user interface and visual display for real-time thermal images, status updates and alerts. Monitoring sensors measure a patient's vital signs during the scan. A remote connection allows clinical staff and safety personnel to review acquired thermal images and the user interface.

The method uses thermal-imaging camera to continuously monitor the patient and their immediate surrounding area. The acquired temperature data and images are processed by a thermal-anomaly detection algorithm, which utilizes a deep-learning process, specifically a convolutional neural network (CNN). This AI model is trained to differentiate between safe and dangerous thermal events.

If no dangerous heating is detected, the MRI scan proceeds. If the scan is interrupted for other reasons, the system can pause and resume image acquisition after mitigation. If the method detects dangerous heating, an alert system is triggered. This alert can notify the MRI technologist via the user interface and visual display, prompting them to manually abort the scan. Alternatively, the alert system can automatically communicate with the MRI apparatus to terminate the scan.

The thermal-imaging camera and its associated components are compatible with both the MRI apparatus and the MRI environment. A user interface displays real-time thermal images and status updates. In some embodiments, the interface integrates with common MRI monitoring sensors, such as heart-rate and respiration monitors, for comprehensive patient monitoring. The user interface can be configured for wireless communication, enabling off-site monitoring by radiologists or safety personnel.

The apparatus and method gauges patient safety by employing temperature-threshold settings that trigger alerts when a predetermined temperature limit is reached in or near the patient. These alerts are communicated directly to the user interface. In critical situations, an automatic interruption mechanism aborts or pauses the MRI procedure to prevent injury to the patient in the MRI machine. Alternatively, a user-override function enables manual control of the system. An artificial intelligence (AI) algorithm is implemented to detect abnormal temperature variations during the MRI procedure and predict potential future temperature increases based on data trends. The artificial intelligence model is trained to interpret thermal-image data to detect a dangerous thermal event and to send to the digital video display and/or audio signal to alert an MRI technologist of the dangerous thermal event.

The method of using the apparatus involves obtaining real-time thermal imaging data; inputting it into the AI model; detecting a dangerous thermal event; engaging the alarm; and terminating the MRI scan if the method determines the event is severe.

### BRIEF DESCRIPTION OF DRAWINGS

FIG. 1 is a diagram of the apparatus of the disclosure

FIG. 2 is a diagram of the workflow thereof

FIG. 3 is a diagram describing a method of training the artificial-intelligence model

### DETAILED DESCRIPTION

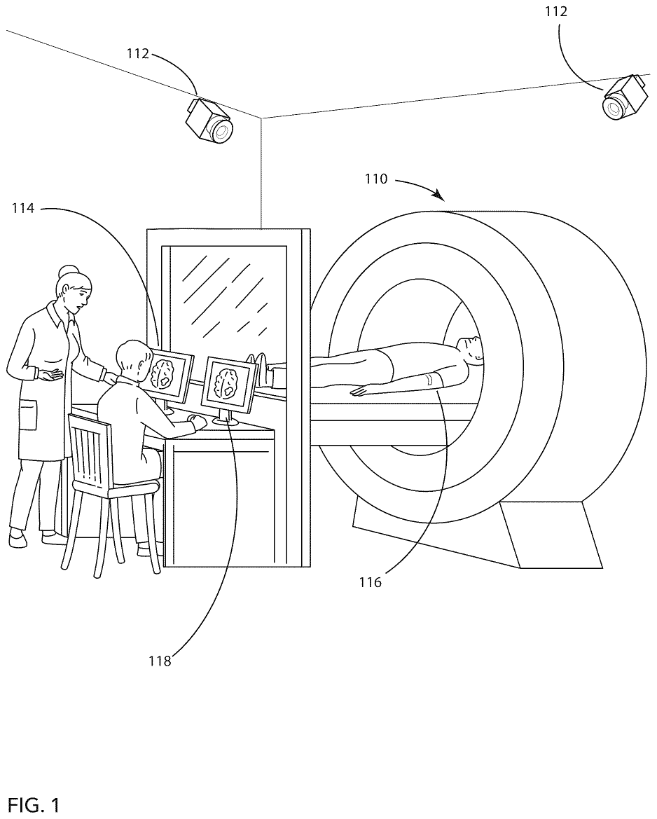

FIG. 1 depicts an MRI apparatus 110 connected to thermal-imaging cameras 112 that detect infrared radiation emitted by objects, and displays them as images that represent temperature variations. A user interface and visual display 114 shows real-time thermal images, status updates and alerts. Monitoring sensors 116 measure vital signs such as heart rate and respiration. A data-acquisition unit 118 is a computer with a software program that receives the thermal images and analyzes them to detect anomalous heating. The data-acquisition unit collects and stores temperature data by use of a data logger and a temperature-variation mapping system. A remote connection provides access to the acquired thermal images, as well as to the user interface, for review by clinical staff and safety personnel.

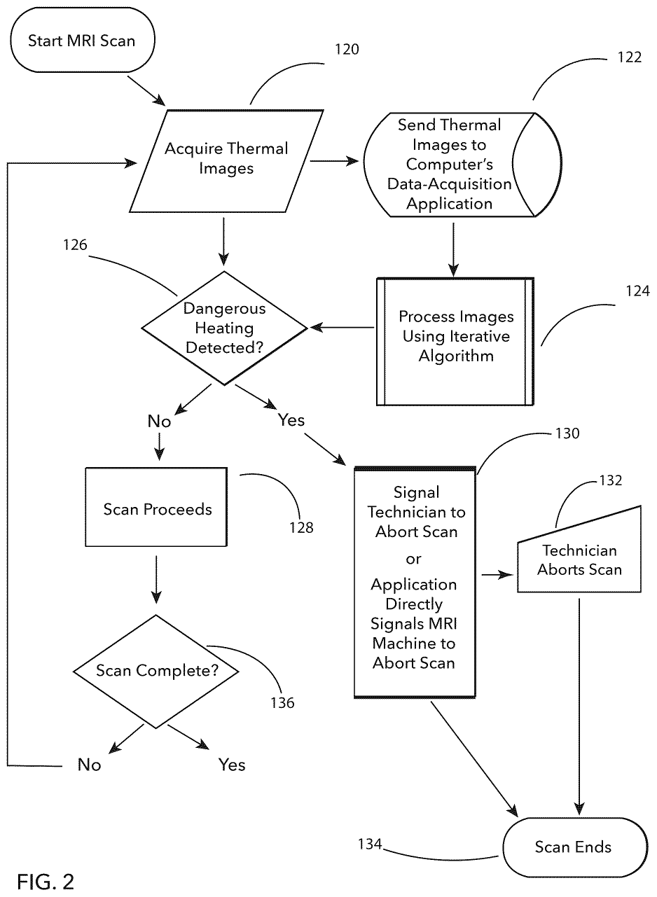

FIG. 2 shows a workflow diagram. The apparatus's thermal-imaging cameras FIG. 1, 112 monitor the patient's temperature as well as that of the immediate surrounding area during MRI scan. A data-acquisition application 122 records temperature readings and relevant data. Acquired images 120 and their data are processed by a thermal-anomaly detection algorithm 124, which analyzes temperature data to detect heat aberrations in order to make a safety determination 126. If no danger is present, the scan proceeds 128. If the scan is not completed 136, the method pauses for mitigation before beginning to acquire images again.

If dangerous heating is detected, an alert system signals 130 to a technologist, through the user interface/visual display, of abnormal heat signals, so that the technologist may abort the scan 132, and the scan ends 134. Alternatively, the alert system communicates with the MRI apparatus to automatically abort the scan 134.

A deep-learning process for image recognition, designed to define a thermal event as dangerous or safe based on an input image, is used in the determination of safe or unsafe MRI heating. In this method, data is first gathered and prepared from thermal images collected from human subjects under clinical conditions Then the image data are categorized by safe/cold temperature vs. unsafe/hot temperatures, forming a defined, structured dataset for training a convolutional neural network (CNN) to determine a final safety analysis. The network learns to automatically extract relevant features from thermal images and then uses these features to classify the thermal event as either dangerous or safe. The model is exposed to training images repeatedly, progressively learning significant features of the images. Over successive iterations, the model refines its understanding, improving its ability to differentiate between various image classes. The trained model is then applied to new/unseen images for classification.

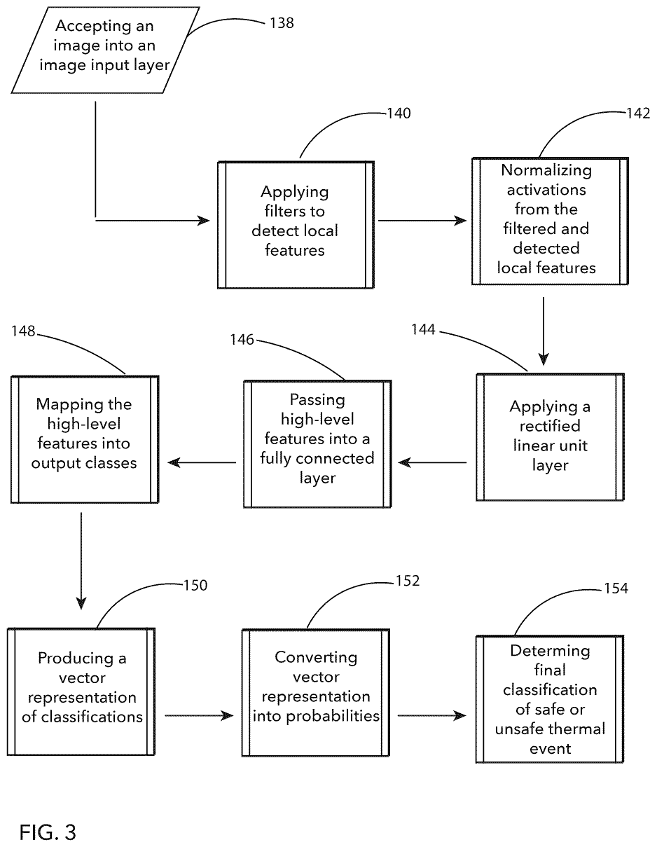

FIG. 3 shows, in detail, the method of training the artificial intelligence model, which involves:

Accepting a thermal image into an image input layer 138: The input layer takes the raw pixel values of the image as input. The dimensions of this layer will correspond to the height, width, and number of channels (e.g., grayscale for one channel, or multiple channels if different thermal spectra are captured) of the input thermal images.

Applying multiple filters to detect local features 140: This step refers to the convolutional layers, which use a set of learnable filters (also known as kernels). Each filter is a small matrix of weights. These filters slide (convolve) across the input image, performing dot products between the filter weights and the local regions of the image they cover. The purpose of these filters is to detect basic local features such as edges, corners, textures, or specific temperature gradients within the thermal image. Differing filters learn to detect differing features. Applying multiple filters results in multiple “feature maps” in which each map highlights the locations and strength of a particular feature detected by its corresponding filter.

Normalizing activations from the filtered and detected local features 142: After features are detected by the filters, their activations (the output values from the convolution operation) are often normalized. This step is crucial for stabilizing and speeding up the training process.

Applying a rectified linear unit layer 144: This is an activation function applied to the output of the convolutional layers (often after normalization). ReLU speeds up training, and often leads to better performance compared to other activation functions like sigmoid or tanh in deep networks

Passing high-level features into a fully connected layer 146: After several convolutional, normalization, and ReLU layers, the network will have learned a hierarchy of features. Initial layers detect simple features, and deeper layers combine these to detect more complex, high-level patterns or objects. Before passing these features to a fully connected layer, the multi-dimensional feature maps are typically flattened into a one-dimensional vector. A fully connected layer (or dense layer) is one where every neuron in the layer is connected to every neuron in the previous layer. These layers are capable of learning non-linear combinations of the high-level features extracted by the convolutional layers.

Mapping the high-level features into output classes 148: The fully connected layers act as classifiers. They take the high-level abstract features and learn how to map them to the predefined output classes. The initial mapping may be to an intermediate representation that distinguishes between “dangerous” and “safe” thermal characteristics.

Producing a vector representation of different classifications (dangerous vs. safe) 150: This vector might have two components; one representing the “score” or “evidence” for the corresponding class.

Converting vector representation into probabilities 152: To interpret the output scores as probabilities, an activation function is applied to the output vector from the final fully connected layer.

Determining a final classification that a thermal event is either dangerous or safe 154: based on the calculated probabilities, a final decision is made. Typically, the class with the highest probability is chosen as the final classification.

1. An apparatus and method for monitoring thermal events in a magnetic resonance imaging scanner comprising:
providing the magnetic resonance imaging scanner; and
at least one thermal imaging camera; and
a first processor storing an artificial intelligence model; and
at least one alarm; and
a digital video display interface; wherein
The artificial intelligence model is trained to interpret thermal image data to detect a dangerous thermal event and to engage the digital video display to engage the alarm, to alert an MRI technologist of the dangerous thermal event.

2. The apparatus of claim 1 wherein:
the alarm is audible.

3. The apparatus of claim 1 wherein:
at least a second processor coupled with the magnetic resonance scanner, the at least one thermal imaging camera, the first processor, the at least one alarm, and the digital video display; wherein
the magnetic resonance scanner is engaged to terminate the MRI scan.

4. The apparatus of claim 1 wherein:
the alarm is visible.

5. A method of using the apparatus of claim 1 for recognizing a dangerous thermal event in a magnetic resonance scanner to terminate a magnetic resonance imaging scan, the method comprising:
obtaining real-time thermal imaging data of patients in the magnetic resonance scanner; and
inputting the obtained data into an artificial intelligence model; and
detecting a dangerous thermal event; and
engaging the alarm; and
determining, in the artificial intelligence model, that the dangerous thermal event is severe; wherein
the magnetic resonance imaging scan is terminated.

6. A method of training the artificial intelligence model of claim 5 comprising:
accepting an image into an image input layer; and
applying multiple filters to detect local features; and
normalizing activations from the filtered and detected local features; and
applying a rectified linear unit layer; and
passing high-level features into a fully connected layer; and
mapping the high-level features into output classes; and
producing a vector representation of different classifications; and
converting vector representation into probabilities; and
deciding a final classification; wherein
the final classification determines if a thermal event is dangerous or safe.
